(19) United States
(12) Patent Application Publication
(10) Pub. No.: US 2006/0119263 A1
(43) Pub. Date: Jun. 8, 2006

(54) Double-side display device and method of making same

(75) Inventors: Shih-Hsien Chen, Shengang Township (TW); Kuang-Tao Sung, Fongyuan City (TW)

Correspondence Address: WARE FRESSOLA VAN DER SLUYS &;ADOLPHSON, LLP, BRADFORD GREEN BUILDING 5, 755 MAIN STREET, P O BOX 224, MONROE, CT, 06468, US

(73) Assignee: AU Optronics Corporation

(21) Appl. No.: 11/007,447

(22) Filed: Dec. 7, 2004

(51) Int. Cl. H05B 33/04; H05B 33/08; H05B 33/10

(52) U.S. Cl. 313/512; 313/511; 445/25

(57) ABSTRACT

A display device, process of manufacturing same, and equipment for performing the process, the display device including a first display residing on a first panel and a second display residing on a second panel, with the displays electrically coupled via an anisotropically conductive material or combination of anisotropically conductive materials having appreciable conductivity along the direction the material is compressed. Conductive pads, having a substantial protrusion from the surface of the panel and arranged in a fan-out style, are typically patterned on the first panel and corresponding conductive pads patterned on the second panel, and the anisotropically conductive material or combination of materials is disposed and compressed so as to electrically couple corresponding pads on the two panels.

### TECHNICAL FIELD

The present invention pertains to the field of opto-electronic devices. More specifically, the present invention pertains to flat panel display devices using organic light emitting diodes.

### BACKGROUND ART

It is desirable for a mobile device such as a cellular handset to be equipped with more than one display. In practice, a larger-size main display is used for showing receiving and transmitting functions when the handset is in use, while a smaller secondary display is used in standby mode for showing information indicating an incoming call or the time of day, for example.

Organic light emitting diodes (OLEDs) are becoming increasingly popular for applications such as flat panel displays, illumination, and backlighting. Due to their low weight and thinness, the OLED display modules are particularly suited for mobile devices. OLED displays are known in the art. In an OLED display, a thin OLED display layer disposed between two electrode layers is deposited on a substrate such as a flat glass panel for mechanical support and protection. The light emitted by the OLED display is transmitted through at least one of the two electrodes made with transparent conductive material. If an OLED display is configured to emit light only through the substrate panel, a transparent electrode (usually an anode) on the substrate side and a reflective non-transparent electrode (usually a cathode) on the opposite side are used.

It is known in the art that two OLED displays can be configured to face opposing directions and be controlled by one single driver circuit. Chien et al (U.S. patent application having publication No. 2004/0075628) discloses a double-sided OLED display module wherein two separate OLED displays are connected by a ribbon or flexible connector. As shown in FIG. 1, the double-sided display module 1 comprises a primary display panel 10 and a secondary display panel 20, electrically connected by a curved connector 30. As shown, the primary display panel 10 has an OLED display 12 disposed on a transparent substrate 14 and the secondary display panel 20 has an OLED display 22 disposed on a transparent substrate 24. A cap 16 is used to protect the display 12 and a cap 26 is used to protect the display 22. The entire display module 1 is controlled by a driver unit 34 mounted on a thin substrate 32.

The ribbon connector 30 is typically made of a flexible, flat substrate having a plurality of electrically conductive lines printed on the substrate. The conductive lines are substantially parallel to each other and communicating the length of the connector. Using this type of connector, it is impractical to use more than one connector to electrically connect two separate displays. Thus, all the connection points or pads on the display panel 10 are substantially disposed on one of the edges on the backside of the substrate 14, and all the connection points or pads on the display panel 20 are substantially disposed on one of the edges on the backside of the substrate 24. Furthermore, each end of the connector 30 must be rigidly attached to backside of the corresponding substrate. Separate caps 16 and 26 must be properly attached to provide a hermetic seal to the displays 12 and 22. Finally, some mechanical device should be used to keep the two display panels 10, 20 in place. This type of design is cost inefficient.

It is thus advantageous and desirable to provide a method to produce a two-sided display device with a favorable production yield and assembly efficiency.

### SUMMARY OF THE INVENTION

The present invention uses an anisotropically conductive material to electrically couple a first display panel and a second display panel for forming a double-sided display device. The double-sided display device has a first side for viewing a first display and an opposing side for viewing a second display. The first display panel has an outside surface facing the first side and an inside surface for disposing the first display. The second display panel has an outside surface facing the second side and an inside surface for disposing the second display. A plurality of first electrically conductive pads are distributed on the inner surface of the first display panel for electrically connecting the first display, and a plurality of electrically conductive pads are distributed on the inner surface of the second display panel for electrically connecting the second display. The anisotropically conductive material is applied between the inside surface of the first display panel and the inside surface of the second display panel for electrically coupling the two display panels. A sealing material is applied between these two inner surface for hermetically sealing the first and second displays.

Thus, the first aspect of the present invention provides a display device. The display device comprises:

a first display residing on a first panel; and

a second display residing on a second panel, wherein the displays are electrically coupled via an anisotropically conductive material or combination of anisotropically conductive materials.

According to the present invention, the display device further comprises:

a plurality of first conductive terminals patterned on the first panel for electrically connecting the first display; and

a plurality of second conductive terminals patterned on the second panel for electrically connecting the second display, the second conductive terminals corresponding to at least some of the first conductive terminals, wherein the anisotropically conductive material or combination of anisotropic conductive materials is disposed so as to electrically couple the first conductive terminals to the second conductive terminals.

According to the present invention, the first display has a display area and the first conductive terminals are distributed over the entire periphery of the display area or part of the periphery.

According to the present invention, the display device has a first side and an opposing second side, wherein

the first panel has a first surface and an opposing second surface, the first surface facing the first side of the display device, and

the second panel has first surface and an opposing second surface, the first surface facing the second side of the display device, and wherein

the first conductive terminals are disposed on the second surface of the first panel, and

the second conductive terminal are disposed on the second surface of the second panel.

According to the present invention, the display device further comprises a control circuit operatively connected to at least part of the first conductive terminals for controlling the first display and the second display.

According to the present invention, the display device further comprises a sealing material disposed between the second surface of the first panel and the second surface of the second panel so as to provide a hermetic seal around the first display and the second display.

According to the present invention, the second panel can be smaller than or equal in size to the first panel.

According to the present invention, the second display can be smaller than or equal in size to the first display.

According to the present invention, the display device is a double-sided OLED display.

The second aspect of the present invention provides a method of making a display device comprising a first display residing on a first panel and a second display residing on a second panel. The method comprises the steps of:

disposing on the first panel a plurality of first conductive terminals electrically connected to the first display;

disposing on the second panel a plurality of second conductive terminals electrically connected to the second display;

electrically coupling the second conductive terminals to at least some of the first conductive terminals via an anisotropically conductive material.

According to the present invention, the display device comprising a first side and an opposing second side, wherein

the first panel has a first surface and an opposing second surface, the first surface facing the first side of the display device, and

the second panel has first surface and an opposing second surface, the first surface facing the second side of the display device, and wherein

the first conductive terminals are disposed on the second surface of the first panel, and

the second conductive terminals are disposed on the second surface of the second panel.

According to the present invention, the method further comprises the step of

disposing a sealing material between the second surface of the first panel and the second surface of the second panel for sealing the first display and the second display.

According to the present invention, the method further comprises the step of

electrically connecting a control circuit to some of the first conductive terminals for controlling the first display and the second display.

The present invention will become apparent upon reading the description taken in conjunction with FIGS. 2A to 8.

### BRIEF DESCRIPTION OF THE DRAWINGS

The above and other objects, features and advantages of the invention will become apparent from a consideration of the subsequent detailed description presented in connection with accompanying drawings, in which:

FIG. 1 is a schematic view of a prior art two-sided OLED display module.

FIG. 2A is a plane view of a primary display, according to one embodiment of the present invention.

FIG. 2B is a cross-sectional view of the primary display of FIG. 2A.

FIG. 3A is a plane view of a secondary display, according to the present invention.

FIG. 3B is a cross-sectional view of the secondary display of FIG. 3A.

FIG. 4 is a cross-sectional view of the two-sided display module, according to the present invention.

FIG. 5A is a schematic representation showing one type of anisotropic conductive material.

FIG. 5B is a schematic representation showing another type of anisotropic conductive material.

FIG. 6A is a plane view of a primary display panel, according to another embodiment of the present invention.

FIG. 6B is a cross-sectional view of the primary display panel of FIG. 6A.

FIG. 7A is a plane view of a secondary display panel, according to the other embodiment of the present invention.

FIG. 7B is a cross-sectional view of the secondary display panel of FIG. 7A.

FIG. 8 is a cross-sectional view of the two-sided display module, according to the other embodiment of the present invention.

FIG. 9 is a flowchart illustrating the method of making a double-sided display device, according to the present invention.

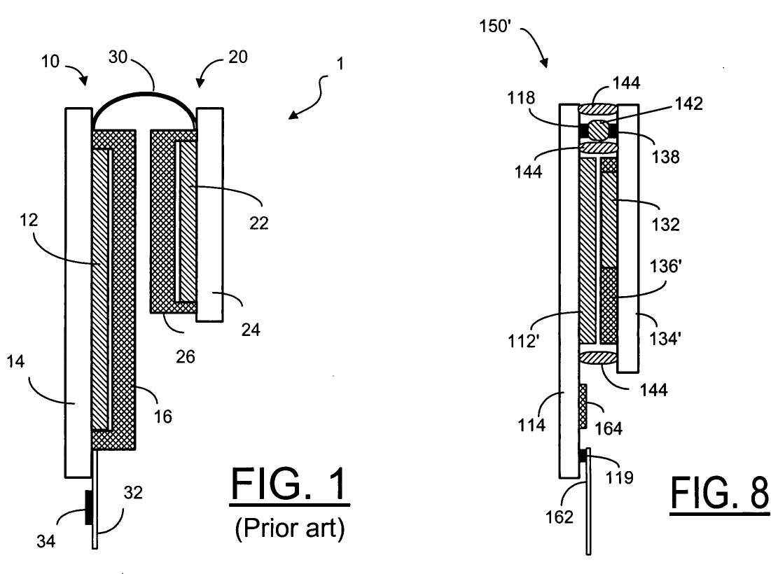

### DETAILED DESCRIPTION OF THE INVENTION

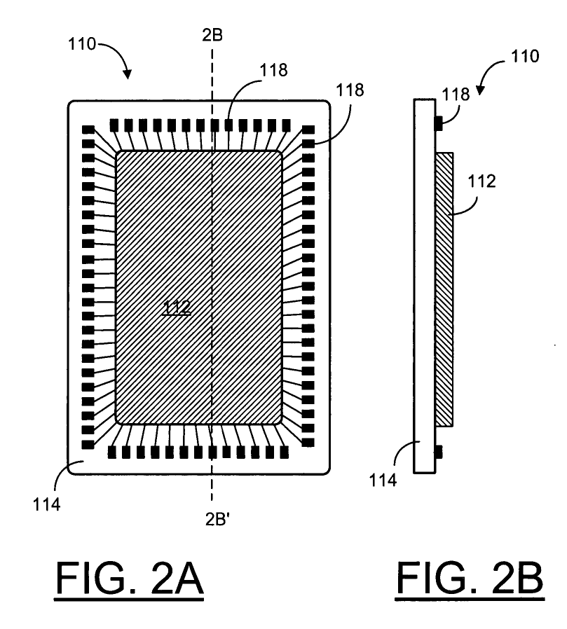

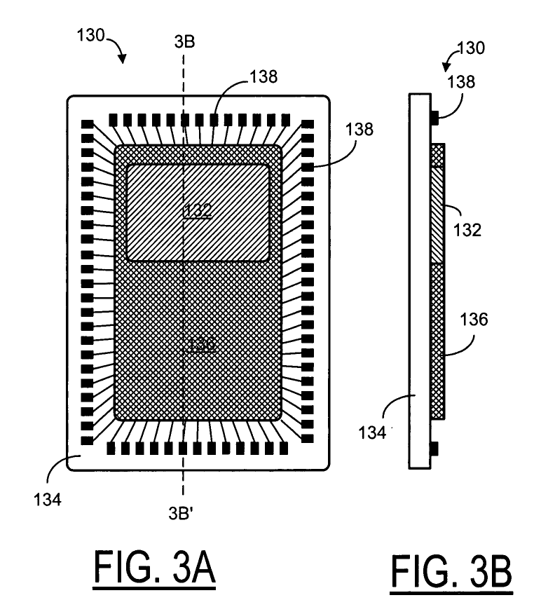

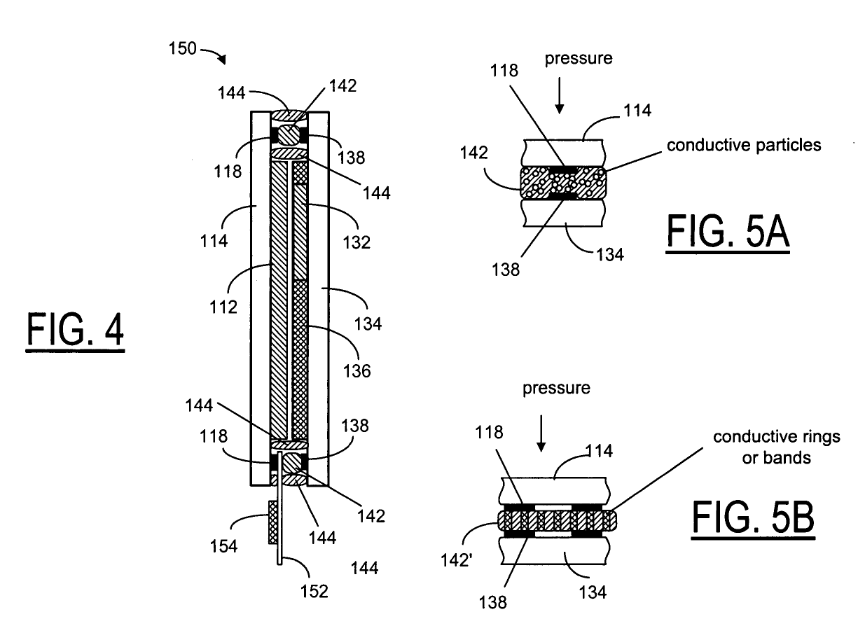

The two-sided OLED display module of the present invention comprises a primary display panel and a secondary display panel assembled together with a sealing material. As shown in FIGS. 2A and 2B, the primary display panel 110 comprises an OLED display 112 disposed on a transparent substrate 114. The panel 110 has a plurality of connection pads 118 fanned out on four sides of display 112. As shown in FIGS. 3A and 3B, the secondary display panel 130 comprises an OLED display 132 disposed on a transparent substrate 134. The secondary display panel 130 further comprises a free design area 136 that can be used for current conductive traces or link termination points (LTPs), for example. The panel 110 has a plurality of connection pads 138 fanned out on four sides of free design area 136, substantially corresponding to the connection pads 118 on the primary panel 110. FIG. 4 shows an assembled two-sided display module 150. As shown, the electrical coupling between the primary panel 110 and 130 is achieved by an anisotropic conductive material 142. It is understood that anisotropic conductive material 142 is applied on the fanned out connection pads 118 surrounding the OLED display 112 of the display panel 110. When the display panel 130 is placed against the display panel 110 such that the connection pads 138 on the display panel 130 are substantially aligned with the corresponding connection pads 118 on the display panel 110, the anisotropic conductive material 142 electrically couples one of the conduction pads 118 to one of the connection pads 138. As illustrated in FIG. 5A, one example of the anisotropic conductive material 142 is an epoxy system comprising a plurality of very stable polymer micro-particles coated with conductive materials such as gold and nickel suspended in a dielectric matrix. The insulator outside the conductive coating of the micro-particles prevents inter-particle conducting from occurring. When the anisotropic conductive material 142 is compressed in some region, the cross section or thickness of the compressed region is changed and the dielectric material between the micro-particles and in places on the surfaces of the micro-particles is squeezed out of the region. As such, the conducting coatings on the micro-particles come into contact with each other and provide a conductive path through the compressed region. In general, the conductive path is substantially along the compression direction. The epoxy system is typically in the form of a fluid until it is cured and the compressing is performed before the curing. As shown in FIG. 5A, the electrical coupling between the primary panel 110 and the secondary panel 130 is through the conduction paths between opposing connection pads 118, 138.

Another example of the anisotropic conductive material is shown in FIG. 5B. As shown in FIG. 5B, the anisotropic conductive material 142′ is made of a non-conductive polymer with a plurality of conductive layers embedded in the non-conductive polymer. Alternatively, the non-conductive polymer is in the form of an elongated cylinder with a plurality of conductive bands provided on the cylinder surface. When the substrate 114 is pressed against the substrate 134, the conductive layers or bands provide a conductive path between opposing connection pads 118, 138.

In order to provide a protective seal on the two-sided display module 150, it is possible to apply a continuous strip of sealing material 144 surrounding the fan-out connection pads 118 and another continuous strip between the fan-out connection pads 118 and the OLED display 112. The sealing material 144 can be a UV curable adhesive, for example. As such, a hermetic seal is achieved. To provide signal connection from the two-sided display module 150 to another electronic device or component, a signal transmission link 152 is attached to some of the connection pads 118 (or 138). The signal transmission link 152 can be a flexible printed circuit (FPC) having a driver integrated circuit (IC) 154. The driver IC can be made by a so-called chip-on-film (COF) method, for example.

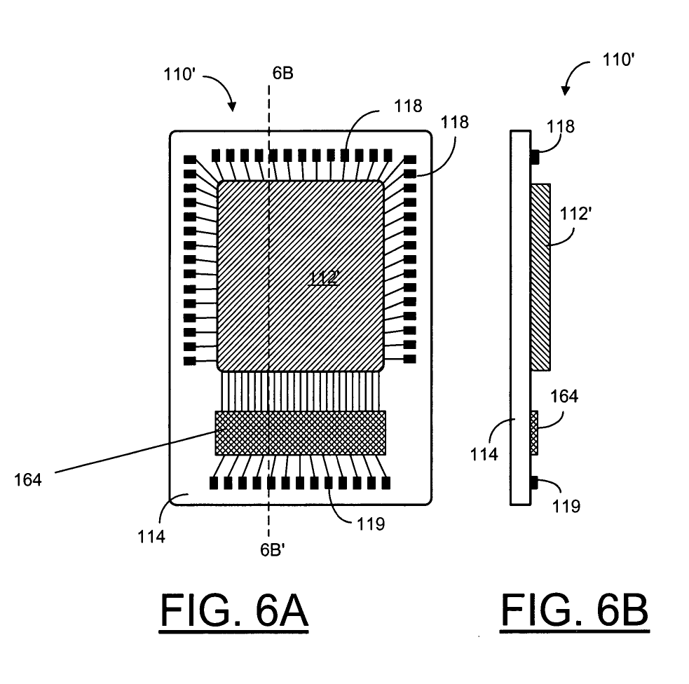

Another embodiment of the present invention is shown in FIGS. 6A to 8. As shown in FIGS. 6A and 6B, the OLED display 112′ on the primary display panel 110′ is shorter than the OLED display 112 as shown in FIG. 2A. The fan-out connection pads 118 are disposed only on three sides of the display 112′. The driver IC 164 is directly disposed on the substrate 114. The connection between the driver IC 164 to an external device or components is carried out through the connection pads 119 via an FPC 162.

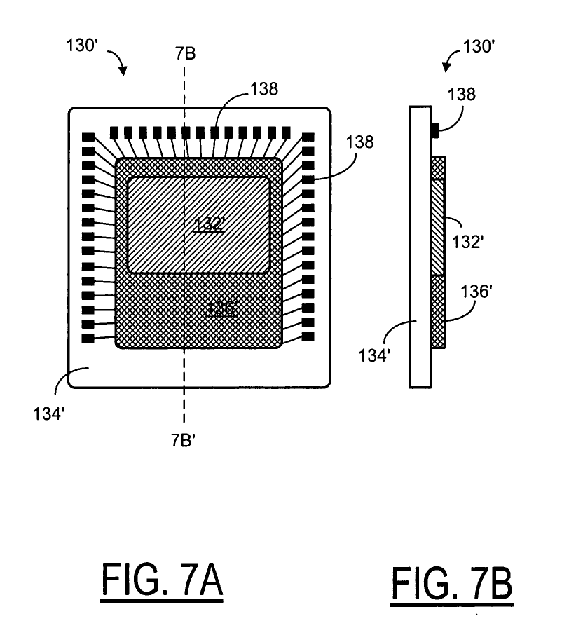

As shown in FIGS. 7A and 7B, the OLED display 132′ on the secondary display panel 130′ is shorter than the OLED display 132 as shown in FIG. 2B. The fan-out connection pads 138 are disposed only on three sides of the display 132′. The assembled two-sided display module 150′ is shown in FIG. 8. In this embodiment, the anisotropic conductive material 142 is applied between the fan-out connection pads 118 of the display panel 110′ and the fan-out connected pads 138 on the display panel 130′, only on three sides of the display 112′. However, the sealing material 144 is applied as two continuous strips.

The present invention has been disclosed in two embodiments. In one embodiment, the electrical coupling between the primary display panel and the second display panel is made via fan-out connection pads and an anisotropic conductive material on all four sides of the display 112. In another embodiment, the electrical coupling between the primary display panel and the second display panel is made via fan-out connection pads and an anisotropic conductive material only on three sides of the display 112′. It should be understood that the electrical coupling between the primary and secondary panels can also made via fan-out connection pays on one or two sides of the display 112 or 112′. Furthermore, the present invention has been disclosed in regard to organic LED displays. The present invention is also applicable to other two-sided flat panel displays such as LTPS displays.

In sum, the primary and secondary panels are joined to form a one-piece module, as shown in FIGS. 5 and 8, with anisotropic conductive material 142, 142′ electrically coupling opposing connection pads in a fan-out pad pattern. One or more continuous adhesive strips are used for hermetically sealing the edges of the two display panels. Preferably, the adhesive strips 144 are made from UV curable material. A mechanical force may be applied perpendicular to the surfaces of the substrates during the curing period to assist the anisotropic conductive material in forming permanent electrical coupling paths between the two displays. As such, the present invention provides a two-sided display module with reduced over all dimensions. The displays in the two-sided display module are hermetically sealed against air and moisture.

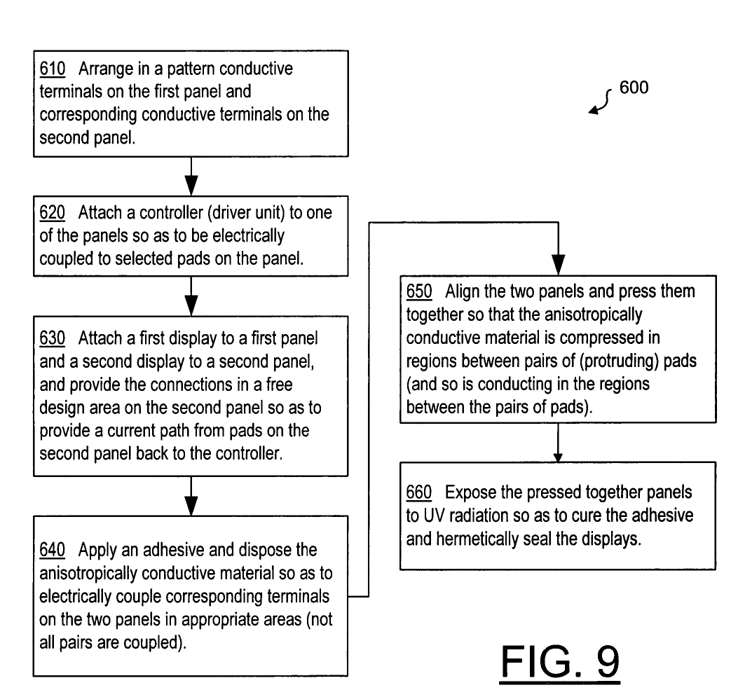

The present invention also provides a process and corresponding equipment for making such a display component, a process having advantageous production yield and assembly efficiency. Referring now to the flowchart 600 of FIG. 9, a process of making a display component according to the present invention includes a first step 610 of arranging in a pattern conductive pads on the first panel and corresponding conductive pads on the second panel, a second step 620 of attaching a controller (driver IC unit) to one of the panels so as to be electrically coupled to selected conductive pads on the panel, a third step 630 of attaching a first display to a first panel and a second display to a second panel, and creating the connections in a free design area on the second panel so as to provide a current path from conductive pads on the second panel back to the controller, a fourth step 640 of applying an adhesive and disposing (distributing) an anisotropically conductive material (on one or the other of the panels, or both) so as to electrically couple corresponding pads on the two panels in appropriate areas (not all pairs are necessarily coupled), a fifth step 650 of aligning the two panels and pressing them together so that the anisotropically conductive material is compressed in regions between pairs of (protruding and opposing) pads to provide electrical connection in the regions between the pairs of pads, and a sixth step 66 of exposing the pressed together panels to UV radiation so as to cure the adhesive and hermetically seal the displays.

The present invention has been disclosed in reference to a double-sided OLED display. However, it is understood that the present invention is also applicable to any double-sided display that has a first display residing on a first panel and a second display residing on a second panel, wherein the first and second displays are electrically coupled via an anisotropically conductive material or combination of anisotropically materials. In particular, the double-sided display allows a viewer to view the first display from one side of the double-sided display and to view the second display from the opposing side of the double-sided panel.

Thus, it is to be understood that the above-described arrangements are only illustrative of the application of the principles of the present invention. Numerous modifications, and alternative arrangements may be devised by those skilled in the art without departing from the scope of the present invention, and the appended claims are intended to cover such modifications and arrangements.

What is claimed is:

1. A display device, comprising:
a first display residing on a first panel; and
a second display residing on a second panel, wherein the displays are electrically coupled via an anisotropically conductive material or combination of anisotropically conductive materials.

2. A display device according to claim 1, further comprising:
a plurality of first conductive terminals patterned on the first panel for electrically connecting the first display; and
a plurality of second conductive terminals patterned on the second panel for electrically connecting the second display, the second conductive terminals corresponding to at least some of the first conductive terminals, wherein the anisotropically conductive material or combination of anisotropic conductive materials is disposed so as to electrically couple the first conductive terminals to the second conductive terminals.

3. A display device according to claim 2, wherein the first display has a display area and the first conductive terminals are distributed over the periphery of the display area.

4. A display device according to claim 2, wherein the first display has a display area and the first conductive terminals are distributed over at least part of the periphery of the display area.

5. A display device according to claim 2, wherein the display device has a first side and an opposing second side, and wherein
the first panel has a first surface and an opposing second surface, the first surface facing the first side of the display device, and
the second panel has first surface and an opposing second surface, the first surface facing the second side of the display device, and wherein
the first conductive terminals are disposed on the second surface of the first panel, and
the second conductive terminal are disposed on the second surface of the second panel.

6. A display device according to claim 5, further comprising a control circuit operatively connected to at least part of the first conductive terminals for controlling the first display and the second display.

7. A display device according to claim 5, further comprising a sealing material disposed between the second surface of the first panel and the second surface of the second panel so as to provide a seal around the first display and the second display.

8. A display device according to claim 1, wherein the second panel is of the same size as the first panel.

9. A display device according to claim 1, wherein the second display is of the same size as the first display.

10. A display device according to claim 1, wherein the second panel is smaller than the first panel.

11. A display device according to claim 1, wherein the second display is smaller than the first panel.

12. The display device according to claim 1, comprising a double-sided LED display.

13. The display device according to claim 1, comprising a double-sided OLED display.

14. A method of making a display device comprising a first display residing on a first panel and a second display residing on a second panel, said method comprising:
disposing on the first panel a plurality of first conductive terminals electrically connecting to the first display;
disposing on the second panel a plurality of second conductive terminals electrically connecting to the second display;
electrically coupling the second conductive terminals to at least some of the first conductive terminals via an anisotropically conductive material.

15. A method according to claim 14, wherein the display device comprising a first side and an opposing second side, and wherein
the first panel has a first surface and an opposing second surface, the first surface facing the first side of the display device, and
the second panel has first surface and an opposing second surface, the first surface facing the second side of the display device, and wherein
the first conductive terminals are disposed on the second surface of the first panel, and
the second conductive terminal are disposed on the second surface of the second panel.

16. A method according to claim 15, further comprising:
disposing a sealing material between the second surface of the first panel and the second surface of the second panel for sealing the first display and the second display.

17. A method according to claim 14, further comprising:
electrically connecting a control circuit to some of the first conductive terminals for controlling the first display and the second display.
